(19) United States
(12) Patent Application Publication
(10) Pub. No.: US 2010/0206863 A1
(43) Pub. Date: Aug. 19, 2010

(54) ELECTRICALLY CONDUCTIVE, FLEXIBLE WEB MATERIAL

(75) Inventor: Wolfgang Ritter, Offstein (DE)

Correspondence Address: LERNER GREENBERG STEMER LLP, P O BOX 2480, HOLLYWOOD, FL, 33022-2480, US

(73) Assignee: BENECKE-KALIKO AG, Hannover (DE)

(21) Appl. No.: 12/719,079

(22) Filed: Mar. 8, 2010

Related U.S. Application Data
(63) Continuation of application No. PCT/EP2008/061807, filed on Sep. 5, 2008.

(30) Foreign Application Priority Data
Sep. 7, 2007 (DE) 10 2007 042 644.7

(51) Int. Cl. B60L 1/02; H05K 1/00; H05B 3/10; H05B 3/00; H05B 1/00

(52) U.S. Cl. 219/202; 174/254; 219/552; 219/211; 219/212

(57) ABSTRACT

An electrically conductive, flexible web material assembly includes a polymer-bonded electrically conductive coating on a flexible, electrically non-conductive carrier, and at least two electrodes for feeding electric current. The electrodes are flexible bands made of an electrically conductive material, and each electrode is fixed on the flat carrier by way of one or more stitches. At least one surface of each electrode has a surface contact with the electrically conductive coating. There are also described a variety of implementations of the electrically conductive, flexible web material assembly in heating elements and in clothing.

### CROSS-REFERENCE TO RELATED APPLICATION

This application is a continuation, under 35 U.S.C. §120, of copending international application No. PCT/EP2008/061807, filed Sep. 5, 2008, which designated the United States; this application also claims the priority, under 35 U.S.C. §119, of German patent application No. DE 10 2007 042 644.7, filed Sep. 7, 2007; the prior applications are herewith incorporated by reference in their entirety.

### BACKGROUND OF THE INVENTION

### Field of the Invention

The present invention relates to electrically conductive, flexible sheet materials and to their use in flexible, sheetlike heating elements, and also in apparel.

Flexible electrically conductive sheet materials, for example electrically conductive textile and electrically conductive foils, are in principle of interest for a whole series of applications. One focus is the use of electrically conductive textiles for screening high-frequency electromagnetic radiation (electrosmog).

There have been various proposals for the use of electrically conductive textiles as conducting tracks or as flexible heating elements (cf. German published patent application DE 42 33 118 A1, for example). However, electrically conductive textiles have hitherto failed to become established for these applications. There are presumably two main reasons for this. First, the overwhelming number of electrically conductive textiles is based on wovens or nonwovens containing a multiplicity of metalized threads or yarns. These metalized threads or yarns are costly and confer an unwelcome stiffness on the textiles. Secondly, sufficient electrical contacting is often problematic and hence high contact resistances occur between the contacting wires and the electrically conductive textile. In the extreme case this can mean that comparatively high electrical power outputs, as required for operating heating elements, can lead to local overheating and to scaling of the contact point.

German published patent application DE 42 33 118 A1 proposes avoiding high contact resistances between an electrically conductive woven fabric and the contact wires by means of an intimate bond between the contact wires and the woven fabric, resulting in a multiplicity of individual contact points.

German utility model DE 20 2005 010 011 U1 (Gebrauchsmuster) proposes that the connecting region of an electrically conductive, coated sheet material be specifically reinforced by way of a metallic layer in order that a stable soldered connection may be established there. This approach is comparatively costly and inconvenient and not satisfactory for comparatively high power outputs.

European published patent application EP 1 284 278 A2 and international patent application publication WO 2005/020246 A1 disclose flexible, electrically conductive sheet materials which include a polymer-bound electrically conductive coating on a flexible electrically nonconductive sheetlike carrier, for example a textile or leather. True, sheet materials of this kind are very much less costly to manufacture than electrically conductive textiles based on metalized threads. However, these materials are particularly prone to present with the problem of high contact resistances in the contact region between the supply lines and the flexible electrically conductive sheet material, since existing methods of establishing electrical contacts between cables and conductive textiles such as crimping or adhering lead to very high contact resistances and other methods such as the above-noted DE 42 33 118 proposal of incorporating the contact wires into the woven fabric, or soldering are not possible.

### SUMMARY OF THE INVENTION

It is accordingly an object of the invention to provide an electrically conductive, flexible sheet or web material, which overcome the disadvantages of the heretofore-known devices and methods of this general type and which is based on a flexible carrier provided with an electrically conductive coating and which makes possible the connecting of electrical supply lines without high contact resistances.

With the foregoing and other objects in view there is provided, in accordance with the invention, an electrically conductive, flexible sheet material assembly, comprising:

a flexible, electrically nonconductive sheetlike carrier;

a polymer-bound electrically conductive coating on the electrically nonconductive sheetlike carrier;

at least two electrodes for supplying electric current formed as flexible tape composed of an electrically conductive material, wherein each of the electrodes is fixed by way of one or more stitches (e.g., elastic threads) on the sheetlike carrier such that at least one face of the electrode is in areal contact (i.e., surface contact) with the electrically conductive coating.

In other words, we have found that this object is achieved according to the present invention by providing an electrically conductive flexible sheet material which a polymer-bound electrically conductive coating on a flexible sheetlike carrier that does not conduct electric current with at least two electrodes configured as a flexible tape composed of an electrically conductive material and fixed on the sheetlike carrier by one or more stitches such that at least one face of the tape-shaped electrode is in sheetlike contact with the electrically conductive coating.

The present invention accordingly provides an electrically conductive flexible sheet material comprising a polymer-bound electrically conductive coating on a flexible, electrically nonconductive sheetlike carrier and at least two electrodes for supplying electric current, the electrodes being configured as a flexible tape composed of an electrically conductive material and each electrode being fixed by means of one or more stitches on the sheetlike carrier such that at least one face of the respective electrode is in sheetlike contact with the electrically conductive coating.

In accordance with an added feature of the invention, the electrodes and the sheetlike carrier are disposed relative to each other such that each by a top side and a bottom side of each the electrode is in contact with the electrically conductive coating.

In accordance with an added feature of the invention, the electrodes and the sheetlike carrier are disposed relative to each other such that each electrode is in contact with the electrically conductive coating by the top side and the bottom side of each electrode being in contact with the electrically conductive coating.

In accordance with an added feature of the invention, two electrodes are disposed at opposite edges of the sheetlike carrier wherein these opposite edges are each turned over such that the respective electrode is in contact with the electrically conductive coating by the top side and the bottom side of the respective electrode being in contact with the electrically conductive coating.

In accordance with an added feature of the invention, a foil material having a both-side metallic surface or a narrow tape formed from metallic or metalized threads is used as electrode material.

In accordance with an added feature of the invention, the electrically conductive coating consists essentially of a polymeric binder and an electrically conductive powder in a powder:binder volume ratio ranging from 1:1 to 10:1. In a preferred implementation of the invention, the electrically conductive powder is selected from powder materials having a noble metal coating disposed on a core of insulator material.

It is also preferred to select the flexible sheetlike carrier from textile, plastics foil, leather and artificial leather.

In accordance with an added feature of the invention, the side which includes the electrically conductive coating is laminated. Further, in one embodiment, both sides are laminated.

With the above and other objects in view, the electrically conductive flexible sheet material according to the above summary is used in flexible electric heating elements. It is also within the invention to use the flexible sheet material assembly in apparel.

With the above and other objects in view there is also provided, in accordance with the invention, an electric heating element comprising an electrically conductive flexible sheet material according to the above summary and having lines for feeding electric current connected to the electrodes, and also means for controlling current flux.

In accordance with an added feature of the invention, the assembly is particularly suited as a heating element for heating areas of a passenger compartment in vehicles. In a preferred embodiment, the element is disposed in a region of the seating area.

Finally, an advantageous implementation of the heating element (one or more) is in its use in a heating blanket.

With the above and other objects in view there is also provided, in accordance with the invention, an item of apparel, which includes an electrically conductive flexible sheet material assembly as outline above, and further:

at least one sensor and/or actuator for receiving information and converting the information into electrical signals;

at least one electrical connector for connecting devices for processing the electrical signals;

wherein said at least one sensor and/or actuator is connected to said at least one connector by way of said electrically conductive flexible sheet material assembly.

Other features which are considered as characteristic for the invention are set forth in the appended claims.

Although the invention is illustrated and described herein as embodied in an electrically conductive, flexible web material, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 shows a perspective view of a preferred embodiment of the invention of the electrically conductive flexible sheet material with supply lines 4;

FIG. 2 shows a section through one edge of the preferred embodiment of an inventive electrically conductive flexible sheet material shown in FIG. 1; and

FIG. 3 shows a plan view of a region of the edge of the preferred embodiment of an inventive electrically conductive flexible sheet material shown in FIG. 1.

### DETAILED DESCRIPTION OF THE INVENTION

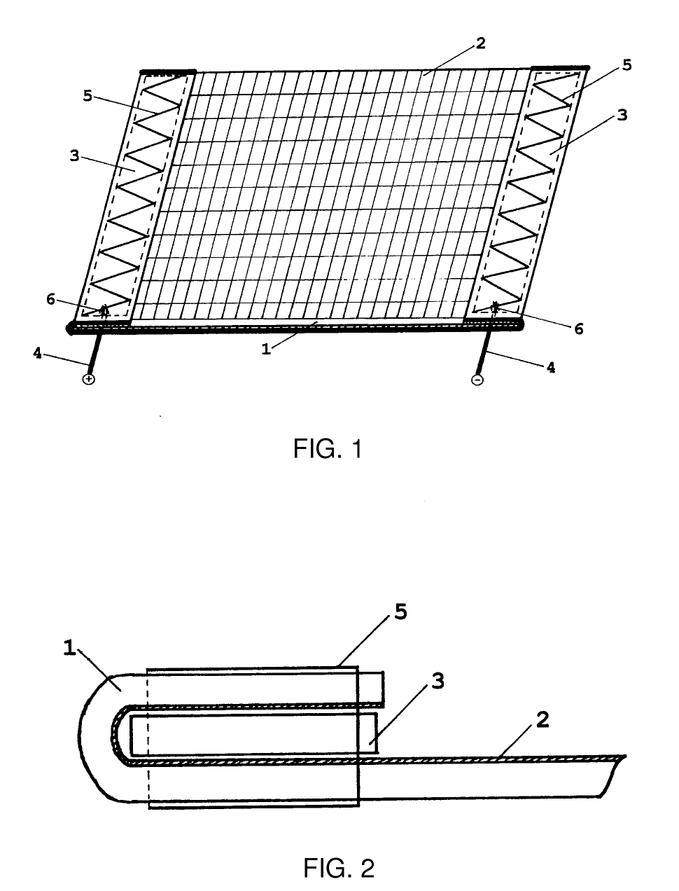

Referring now to the figures of the drawing in detail and first, particularly, to FIG. 1 thereof, there is shown an electrically conductive flexible sheet material comprising a polymer-bound electrically conductive coating 2 on a flexible electrically nonconductive sheetlike carrier 1 and at least two electrodes 3 for supplying electric current.

Suitable flexible sheetlike carriers 1 that do not conduct electric current are for example textile materials such as wovens, knits or nonwovens, leather, plastics foils and artificial leather. In one preferred embodiment, the sheetlike carrier comprises a textile material, more particularly a woven fabric, or artificial leather.

The textile materials can be constructed of natural fiber yarns, synthetic fiber yarns and/or blend yarns, in which case the wovens typically have an areal weight in the range from 50 to 400 g/m², preferably 80 to 250 g/m². Useful fiber materials include in principle any fiber materials customarily used to produce textiles. This includes cotton, wool, hemp fiber, sisal fibers, flax, ramie, polyacrylonitrile fibers, polyester fibers, polyamide fibers, viscose fibers, silk, acetate fibers, triacetate fibers, aramid fibers and the like and also blends thereof. Also suitable are glass fibers and blends of the aforementioned fiber materials with glass fibers, for example glass fiber-Kevlar blends. Preference is given to using a carrier material which is thermally stable, for example up to temperatures of 200° C. or higher. Examples of some thermally stable carrier materials are textiles based on glass fibers and/or aramid fibers or based on blends of glass fibers and/or aramid fibers with conventional fibers such as cotton, flax, sisal, hemp, which consist predominantly, i.e., to an extent of at least 50%, of aramid and/or glass fibers; and also leather or artificial leather.

The conventional sheetlike carrier 1, which is also referred to as a sheet carrier 1 or a sheet substrate 1, is not conductive of electric current and includes a polymer-bound electrically conductive coating 2. Such electrically conductive flexible coatings and also flexible sheet materials including such a coating on a flexible electrically nonconductive sheetlike carrier are described, for example, in European patent EP 1284278, U.S. Pat. No. 5,786,785 and WO2005/0200246, the disclosure of which is hereby incorporated herein by reference in their entirety. These electrically conductive coatings comprise polymer-bound coatings constructed substantially of one or more binder polymers and a finely divided powder, which conducts the electric current.

Useful electrically conductive powders (powders P) include in principle any electrically conductive powder materials known for this purpose, examples being metal powders such as copper powders or zinc powders, carbon black powders, electrically conductive polymers, for example polythiophenes, polypyrroles, polyacetylenes and the like, and also carbon fibers as customarily used for electrostatic discharge protection (antistaticization) of surfaces. Preferably the powder material comprises a finely divided material whose particles have a core-shell morphology, wherein the shell is formed by a material which conducts electric current and the core consists of an insulator material. Preference is given to electrically conductive powders of core-shell morphology, the powder particles of which include a noble metal coating, for example a silver coating, on an insulator material.

Useful noble metals for the noble metal coating include in principle gold and silver and alloys thereof and also alloys thereof with alloyable metals. The noble metal content in the alloys is typically at least 50% by weight, preferably at least 70% by weight. Especially silver or a silver-containing alloy whose silver content is preferably at least 50% by weight and particularly at least 70% by weight, based on the alloy, will prove particularly useful as noble metal coating. Useful alloyable metals include copper, gold, platinum metals, zinc, nickel or other metals forming alloys with gold and/or silver.

Useful as insulator material for the core are, in particular, oxidic materials, for example ceramic materials, plastics and, in particular, glass. Suitable glasses include customary alkali metal and alkaline earth metal silicate glasses and also borosilicate glasses, aluminosilicate glasses, borate glasses, germanate glasses, phosphate glasses and the like. The core can be solid, or is preferably configured as a hollow sphere. Useful electrically conductive powders include in principle metal powders having a noble metal coating, i.e., the core of such powders is a non-noble metal, for example copper, zinc, nickel, iron, tin and the like, or an alloy consisting predominantly of these non-noble metals.

The core and hence also the powder particles preferably have a regular shape, for example a spherical or ellipsoidal shape where the ratio of the largest diameter to the smallest does not exceed a value of 5:1, in particular 2:1.

The powder particles P generally have a median diameter in the range from 1 to 150 μm, frequently 1 to 100 μm, preferably 2 to 70 μm, in particular 5 to 50 μm, more preferably 10 to 40 μm and even more preferably 10 to 30 μm. In one specific embodiment, the median diameter is in the range from 10 to 20 μm. The D₁₀ value of the particles is preferably not below 2 μm and in particular in the range from 4 μm to 25 μm. The D₉₀ value of the powder particles will preferably not exceed a value of 100 μm and in particular 70 μm and more particularly is in the range from 15 μm to 60 μm. The D₁₀ value and the D₉₀ value will be understood by a person skilled in the art to refer to the particle diameter which, respectively, 10% and 90% by weight of the powder particles are smaller than. Correspondingly, the median particle diameter relates to the weight median and logically corresponds to the diameter which 50% by weight of the particles are bigger or smaller than, respectively.

The weight fraction of noble metal and noble metal alloy in powder P is generally at least 3% by weight and preferably at least 5% by weight and will generally not exceed a value of 70% by weight and in particular 50% by weight, all based on the total weight of the powder. More particularly, the weight fraction in question is in the range from 10% to 40% by weight and more preferably in the range from 15% to 35% by weight.

The powders P used in the electrically conductive coatings are known and commercially available. Suitable electrically conductive powders P having a core of electrically nonconductive material are marketed for example under the trade name of Conduct-O-Fil® Silver Coated Hollow Glass Spheres (borosilicate glass, 20 to 33±2% silver), for example the grades SH230S33, SH400S33, SH400S33; Conduct-O-Fil® Silver Coated Glass Spheres (4 to 20±2% silver), for example the grades S-2429-S, S-3000-S, S-3000-S2E, S-3000-S2M, S-3000-S3E, S-3000-S3M, S-3000-S3N, S-3000-S4M, S-4000-S3, S-5000-S2, S-5000-S3, S-2429-S, S-2429-S, S-2429-S, and Conduct-O-Fil® Silver Coated Hollow Ceramic Additive (16 to 30±2% silver), for example the grades AG-SL 150-16-TRD and AG-SL 150-30-TRD, available from Potters Industries Inc., Valley Forge, Pa., or from Potters-Ballotini, Kirchheim-Bolanden, Germany.

The silverized powder of metal comprises in particular silverized powder of copper, for example silverized copper platelets, preferably having a size in the range from 1 to 100 μm. The silver content is generally in the range from 1% to 50% by weight, for example in the range from 5% to 25% by weight, based on the metal powder. Silverized metal powders, in particular silverized copper powders, for example in the form of silverized metal platelets, are known and are marketed for example under the name of KONTAKTARGAN® from Eckart, Fürth, Germany.

In a first embodiment, the electrically conductive powder comprises exclusively (i.e. at no less than 99%, based on the total weight of the powder) at least one powder having a core of electrically non-conductive material. In a particularly preferred embodiment, the powder used comprises silver-coated glass balloons having a silver content in the range from 15% to 35% by weight and a median particle diameter in the range from 10 to 20 μm. In a further preferred embodiment, the powder used comprises silver-coated solid glass balls having a silver content in the range from 4% to 20% by weight and a median particle diameter in the range from 10 to 40 μm.

In another preferred embodiment, the electrically conductive powder used comprises a mixture of a powder having a core of electrically non-conducting material, for example silver-coated glass balloons, and a metal powder with noble metal coating, for example the silverized powder of copper described herein. The weight ratio of metal powder with noble metal coating to the powder with electrically non-conductive core material is then preferably in the range from 5:1 to 1:5 and in particular in the range from 5:2 to 1:5.

The use of other finely divided, electrically conductive materials EM, for example metal powders, such as copper powder or zinc powder, carbon black powder, electrically conductive polymers, for example polythiophenes, polypyrroles and the like or polythiophene-polystyrenesulfonate mixtures, or carbon fibers as typically used for antistaticization of surfaces (i.e., electrostatic discharge protection), is likewise possible. The proportion of such materials in the electrically conductive coating will preferably not exceed 30% by weight and in particular 20% by weight, based on the electrically conductive powder. Preference is given to the co-use of electrically conductive polymers, for example in an amount of 0.5% to 20% by weight, based on the electrically conductive powder, for example polythiophenes, polypyrrols and the like or polythiophene-polystyrenesulfonate mixtures. Examples of such polymers are in particular poly(3,4-(ethylenedioxy)thiophene)/polystyrenesulfonate, marketed under the trade name of Baytron® P by Bayer AG, Leverkusen, Germany.

The electrically conductive coating further comprises a polymeric binder (binder B). This generally comprises a film-forming polymer which, if appropriate at elevated temperature, is capable of forming a coherent film on a surface. The polymer has the role of a binder and leads to adherence of the electrically conductive powder to the surface of the carrier material.

The weight ratio of polymeric binder B to powder P is preferably in the range from 1:1.1 to 1:20, in particular in the range from 1:1.2 to 1:15, more preferably in the range from 1:1.4 to 1:8 and even more preferably in the range from 1:1.5 to 1:5.

It is preferable for the polymer to have a glass transition temperature T_{G} in the range from −40 to 100° C., preferably −20 to +60° C. and especially −10 to +40° C. When the polymeric binder comprises a plurality of polymeric components, at least the main constituent should have a glass transition temperature in this range. More particularly, the glass transition temperature of the main constituent is in the range from −20° C. to +60° C. and more preferably in the range from −10° C. to +40° C. All the polymeric binder components preferably have a glass transition temperature in these ranges. The surface may be tacky when the glass transition temperature is too low. The reported glass transition temperatures are based on the midpoint temperature determined by DSC in accordance with ASTM-D 3418-82. In the case of crosslinkable binders, the glass transition temperature relates to the uncrosslinked state.

Examples of film-forming polymers useful as binder are based on the following classes of polymer:
(1) polyurethane resins;
(2) acrylate resins (straight acrylates: copolymers of alkyl acrylates and alkyl methacrylates);
(3) styrene acrylates (copolymers of styrene and alkyl acrylates);
(4) styrene-butadiene copolymers;
(5) polyvinyl esters, especially polyvinyl acetates and copolymers of vinyl acetate with vinyl propionate;
(6) vinyl ester-olefin copolymers, for example vinyl acetate-ethylene copolymers;
   (7) vinyl ester-acrylate copolymers, for example vinyl acetate-alkyl acrylate copolymers, and also vinyl acetate-alkyl acrylate-ethylene terpolymers;
   (8) silicone rubbers (polysiloxanes).

Such polymers are known and commercially available, for example, polymers of the classes (2) to (7) in the form of aqueous dispersions under the names ACRONAL, STYROFAN, BUTOFAN (BASF-AG), MOWILITH, MOWIPLUS, APPRETAN(Clariant), VINNAPAS, VINNOL (WACKER). Aqueous polyurethane dispersions (1) suitable for the process of the present invention are in particular those used for coating textiles (see for example J. Hemmrich, Int. Text. Bull, 39, 1993, No. 2, pp. 53-56; “Aqueous polyurethane coating systems” Chemiefasern/Textilind. 39 91 (1989) T149, T150; W. Schröer, Textilveredelung 22, 1987, pp. 459-467). Aqueous polyurethane dispersions are commercially available, for example under the trade names Alberdingk® from Alberdingk, Impranil® from BAYER AG, Permutex® from Stahl, Waalwijk, Netherlands, from BASF Aktiengesellschaft or are obtainable by known processes as described for example in “Herstellverfahren für Polyurethane” in Houben-Weyl, “Methoden der organischen Chemie”, volume E 20/Makromolekulare Stoffe, p. 1587, D. Dietrich et al., Angew. Chem. 82 (1970), p. 53 ff. Angew. Makrom. Chem. 76, 1972, 85 ff. and Angew. Makrom. Chem. 98, 1981, 133-165, Progress in Organic Coatings, 9, 1981, pp. 281-240, or Römpp Chemielexikon, 9th edition, volume 5, p. 3575.

The binders may be self-crosslinking, i.e. the polymers have functional groups (crosslinkable groups) which react with each other or with a low molecular weight crosslinker by bond formation in the course of drying of the composition with or without heating.

In addition to the polymer and the electrically conductive powder, the electrically conductive coatings may further comprise up to 20% by weight, but generally not more than 10% by weight, of further auxiliaries. These include UV stabilizers, dispersing assistants, surface-active substances, thickeners, defoamers, foam-forming agents, foam stabilizers, agents for setting the pH, antioxidants, catalysts for any postcrosslinking, hydrophobicizing agents and also preservatives and colorants. In general, the polymer and the powder together comprise at least 80% by weight and frequently at least 90% by weight, based on the total weight of the electrically conductive coating.

The production of an electrically conductive coating on a flexible carrier which does not conduct electric current, or to be more precise on carrier material 1, can be carried out similarly to known processes for applying coatings to flexible sheetlike carriers, for example by printing, blade coating, slop padding, spread coating and the like, as described, for example, in the above-noted European patent application EP 1 284 278 or international application WO 2005/020246. Such processes are familiar to persons of skill in the arts of textile technology.

The electrically conductive coating can be uniform, as described in EP 1 284 278, or partial, as described in WO 2005/020246. The term “uniform” should be understood as meaning that the coating has a uniform thickness in the coated region of the sheetlike carrier. A coating is said to be partial when the coating forms a pattern of a multiplicity of coherent coated areas and includes a multiplicity of noncoherent uncoated areas. Examples thereof are the net-shaped patterns as described in WO 2005/020246. In partial coatings, the coated areas generally comprise 10 to 70% and particularly 20 to 60% of the total area of the partial coating, i.e., of the coated and uncoated regions.

The coating generally has a thickness of at least 5 μm in the coated regions. More particularly, coating thickness in the coated regions is in the range from 10 μm to 200 μm. The add-on of polymer-bound coating is generally in the range from 5 to 200 g/m², frequently 10 to 150 g/m², and in the regions of a partial application the add-on is typically in the range from 5 to 100 g/m² and particularly in the range from 10 to 80 g/m², and in the case of a uniform coating the add-on is typically in the range from 10 to 200 g/m² and particularly in the range from 20 to 150 g/m².

In one preferred embodiment of the present invention, the electrically conductive sheet material includes a partial application in a subregion at least. In the region of the electrodes 3, the electrically conductive coating 2 is preferably uniform, but can also be partial. The electrically conductive coating 2 can also be configured in the form of one or more discrete conducting tracks, in which case each conducting track has an electrode 3 of tape-shaped design at their starting and end points, or a bundle of multiple conducting paths have an electrode 3 of tape-shaped design at their starting and end points.

In accordance with the present invention, the electrodes 3 are configured as a flexible tape composed of an electrically conductive material. The terms “tape” and “tape-shaped” are to be understood as meaning that the thickness of the electrode is distinctly less than its width with the ratio of width to thickness generally being at least 5:1 and frequently at least 10:1. In general, however, the width:thickness ratio does not exceed a value of 100:1 and particularly 50:1. The width of electrode 3 is typically in the range from 3 mm to 2 cm and frequently in the range from 5 mm to 1.5 cm. The thickness of the tape-shaped electrode 3 is typically in the range from 0.1 mm to 3 mm and frequently in the range from 0.2 mm to 2 mm. The length of the electrode naturally depends on the size of the region through which current flux is desired, and also on the intended power input of electrical energy. It can be in the range from a few centimeters up to several meters, for example in the range from 1 cm to 200 cm, frequently 10 cm to 100 cm. Electrode length and width are typically chosen such as to give a contact area of at least 0.1 cm², preferably at least 0.2 cm² and particularly at least 0.3 cm² per watt of electrical energy. The upper limit of the contact area is naturally not subject to any restrictions or only subject to cost-based restrictions, and frequently amounts to not more than 20 cm²/watt and particularly not more than 10 cm²/watt.

The size of such sheet materials naturally depends on the desired use. In general, however, an electrode separation of 1.5 m is not exceeded. Frequently, the separation between two adjacent electrodes is in the range from 10 cm to 1.5 m and particularly in the range from 20 cm to 1 m. Electrode separation is measured in terms of the distance between the area centroids of the electrodes.

The electrode material can in principle be any metallic tape-shaped structure, which can be flexible or rigid and preferably is flexible. Suitable are for example metallic or metalized foils which have a metal surface on both sides, and also so-called narrow tapes, i.e., wovens or formed-loop knits formed from metallic or metalized threads. Useful metals for the electrode materials include, in particular, copper, aluminum and tin and also noble metals, for example silver, gold and/or platinum and alloys thereof. The foil materials can be metal foils, for example copper or tin foils or to be more precise tapes formed from these foil materials, or metalized foils. Metalized foils are foils having a coating of metal on an inert carrier, for example polyester and/or polyamide. In one preferred embodiment of the present invention, the electrode material used is a tape of a copper, tin or aluminum foil material wherein the metal foil can be tinned, silverized or gilded. The metal foils can also be self-adhesive.

In accordance with the present invention, each electrode 3 is fixed by one or more stitches 5 on the sheet carrier 1 such that at least one face of the respective electrode 3 is in areal (i.e., sheetlike) contact with the electrically conductive coating 2. The term areal is to be understood as meaning a bounded part of a space on a surface, two-dimensional contact, a region of a substantially flat surface. The stitches are preferably such stitches as lead to the electrode becoming pressed against the electrically conductive coating. Suitable are stitches embodied as blind stitch, cross stitch, zigzag stitch, diamond stitch or the like. It is also conceivable to have combinations of two or more stitches, which can be embodied in the same stitch or with different stitches. Preferably, at least one stitch penetrates the electrode material. The aforementioned stitches can also be embodied as double thread stitch.

The stitch is preferably formed by an elastic thread material. Useful thread materials include, in particular, elastic thread materials, plastics materials such as PUE threads, i.e., threads having polyester and polyurethane constituents (=elastane threads), for example the thread materials marketed under the trade names of Dorlastan, Lycra and spandex. An overview of such fiber materials is to be found for example in M. Peter, Grundlagen der Textilveredelung, 12^{th} edition, Deutscher Fachverlag, pages 252f. Metal threads or metalized threads are also suitable.

In addition to fixing via one or more threads it is also possible to use other means for augmenting the fixing, for example adhesive materials, for example electrically conductive adhesives, but also conventional adhesives.

In a first embodiment of the present invention, the fixing of the electrodes 3 on the sheetlike carrier 1 is effected such that only one face of the respective electrode 3 is in sheetlike contact with the electrically conductive coating 2. In one preferred embodiment, at least one and particularly both of the electrodes 3 and the sheetlike carrier 1 are disposed relative to each other such that at least one electrode 3 and preferably two electrodes 3 are in contact with the electrically conductive coating 2 by the top side and the bottom side (i.e., the sheetlike sides) of the electrodes 3 each being in contact with the electrically conductive coating 2. This can be accomplished for example by the sheetlike carrier being turned over in those regions in which a contact with the electrode is to be achieved, so that the electrically conductive coating comes to lie internally in the turnover region, and the tape-shaped electrode being fixed in this turnover region using one or more stitches. In this way, the electrode is in contact with the electrically conductive coating 2 by the top side and the bottom side of the electrode being in contact with the electrically conductive coating 2. In preferred embodiments of the invention as is shown in FIG. 1, the edges of the electrically conductive sheet material are turned over in the direction of the electrically conductive coating and the electrodes 3 are each disposed internally in the turned-over regions. One or more stitches are used to fix the respective electrode 3 and the respective turnover, as described above.

The electrodes 3 make it possible to connect any desired electrical leads 4, particularly the connection to metal cable, for example braided cable. The electrical lead 4 can be connected to the electrode 3 in a conventional manner, for example in the case of metallic leads by soldering or adhering with an electrically conductive adhesive or by crimping.

The numerals in FIGS. 1 to 3 designate the following elements:
1 (sheetlike) carrier
2 (electrically conductive) coating
3 electrode
4 supply line
5 stitch
6 material lock site

Referring once more to the drawing in detail, FIG. 1 shows such an arrangement with two electrodes 3 disposed at opposite edges of the sheetlike carrier 1, these opposite edges each being turned over such that the electrically conductive coating 2 is on the inside of the turnover region, the respective electrodes 3 likewise being disposed in the turnover, so that their top side and their bottom side are in contact with the electrically conductive coating 2. The two turnovers and hence also the electrode in the embodiment of FIG. 1 are each fixed by zigzag stitches 5, although other stitches are likewise suitable for fixing. FIG. 1 additionally shows supply lines 4 for electric current, which are fixed to the respective electrodes, for example by a soldered or adhered site 6, for example by soldering or adhering with an electrically conductive adhesive or by crimping (not shown). In the embodiment shown in FIG. 1, the electrically conductive coating is configured as a partial coating in the form of a line pattern as described in WO 2005/020246. The hatching shown in the figure is not true to scale and is only intended to indicate the line pattern. However, the coating can also be made uniform and is preferably made uniform in the region of the electrodes 3 in order that good contacting of the electrodes with the electrically conductive coating may be achieved there.

FIG. 2 shows a schematic section along a stitched site through the embodiment, shown in FIG. 1, of an inventive electrically conductive sheet material (without electrical supply lines 4) to indicate that, as result of the sheetlike carrier being turned over in the edge region, the tape-shaped electrode 3 is in contact with the electrically conductive coating 2 with both its bottom side and its top side, and is fixed by the stitch 5.

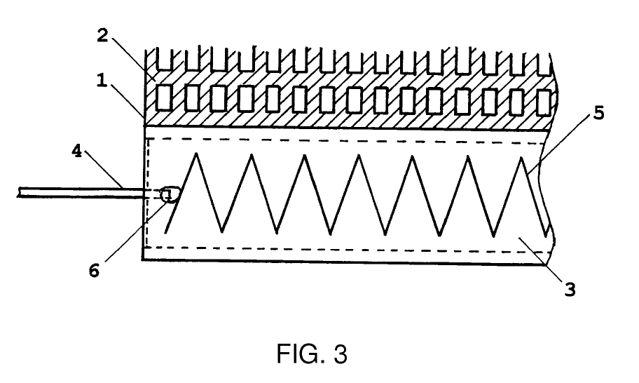

FIG. 3 shows a plan view of this edge region (with supply lines 4) wherein the electrode 3, which is fixed by a stitch 5, is depicted with a soldered or adhered site (6) for connecting the supply line 4 and wherein the line pattern of the coating 2 on the carrier 1 is depicted.

The electrically conductive flexible sheet materials can be laminated one-sidedly or both-sidedly. In one preferred embodiment, at least that side of the sheet material which carries the electrically conductive coating is laminated. In another, similarly preferred embodiment, the electrically conductive sheet material is laminated on both sides. Lamination is effective in promoting better and more uniform removal of heat at higher power inputs. Examples of suitable laminating materials are textiles such as wovens, formed-loop knits, felts, non-wovens and fibrous nonwoven webs, and also plastics foils, paper and foam foils, for example polyester urethane foam foils or polyether urethane foam foils. The laminating of the inventive electrically conductive flexible sheet material can be effected similarly to the laminating of conventional flexible sheet materials as familiar to a person skilled in the arts of textile technology for example (see H.K. Rouette, Lexikon für Textilveredelung, Laumannsche Verlagsgesellschaft, Dülmen 1995, pages 950 ff).

The electrically conductive sheet materials of the present invention can be used for a multiplicity of applications. Since they withstand high power inputs, they are particularly useful in flexible heating elements which are based on the principle of electrical resistance heating. Accordingly, the present invention further provides for the use of an electrically conductive flexible sheet material as defined herein in flexible electrical heating elements.

Such flexible electrical heating elements, in addition to the electrically conductive flexible sheet material of the present invention, generally further include supply lines 4 for feeding electrical current and also means for controlling current flux, for example on-off switches, potentiometers and also other electrical control circuitry. In addition, the electrically flexible heating elements may also contain one or more means for temperature control, for example thermosensors, which can optionally be connected to a control circuit for controlling the electric current flux and thus enable uniform thermostating of the electrical heating element.

The electrical heating elements of the present invention can be used in many different ways, for example for heating floor, wall and ceiling elements, for heating user-contacted surfaces, for example in heating blankets or heated places for living things to lie, seats and chairs, for example automotive seats, grips, handles or steering wheels, and also for heating any other surfaces where heating is desired.

A particularly preferred embodiment of the present invention relates to the use of heating elements of the present invention for heating areas in passenger compartments of vehicles, specifically automotive vehicles. For instance, they are useful for heating walls in driver cabins of trucks and also, particularly, for heating user-contacted areas of a passenger compartment such as automotive seats or steering wheels.

A particularly preferred embodiment of the present invention therefore relates to an automotive seat which at least in the region of the seating area, optionally also in the region of the back rest, comprises at least one heating element of the present invention. The arrangement of such electrical heating elements in automotive seats is known from the prior art, for example from G. Schanku, Forscheda 8908480, page 207 and also from German published patent application DE 42 33 118 A1, which is herewith incorporated by reference.

The electrically conductive sheet materials of the present invention can also be used in apparel. For example, the electrically conductive sheet materials of the present invention can be used to electrically connect sensors and/or actuators incorporated in the apparel to receive information items there about states of the body or its movements and convert them into electrical pulses or signals to one or more connectors serving to connect an instrument for further processing or forwarding information items provided by the sensors and/or actuators.

The examples which follow serve to elucidate the invention and are not to be understood as restricting.

The experiments which follow were carried out using composition Z1 from the above-noted European patent application EP 1 284 278.

### Example 1

Print paste Z1 was screen printed, 60 mesh, uniformly at 100% area coverage onto commercially available artificial leather (Benecke Kaliko), so that a dry coating having an add-on of about 40 g/m² resulted. Application of the composition was followed by drying at 180° C. for 2 minutes. The coating was about 20-40 μm in thickness.

The artificial leather thus obtained was cut to remove rectangular specimens measuring 40 cm by 45 cm. The short sides of the specimens had a self-adhesive copper tape (1 cm wide, 40 cm long, 0.38 mm thick) adhered to them over their entire length. The edge was turned over inwardly and the turnover thus formed was zigzag stitched together with an elastane thread. The ends of the two copper tapes had braided cable composed of copper, 1.5 mm² in cross section, attached to them by soldering. The separation between the electrodes was 40 cm.

### Example 2

The carrier material used was a 63 P polyester-polypropylene fibrous nonwoven web from Gutsche having a basis weight of 79 g/m². A net-shaped pattern formed from two mutually orthogonal sets of parallel stripes, as described in WO 2005/020246, was then screen printed onto the fibrous nonwoven web such that a dry add-on of 30 g/m² and a powder add-on of 20 g/m² resulted. Area covered was 64%. This was followed by drying at 180° C. for 2 minutes.

The artificial leather thus obtained was cut to remove rectangular specimens measuring 40 cm by 45 cm. The short sides of the specimens had a self-adhesive tin tape (1 cm wide, 40 cm long, 0.38 mm thick) adhered to them over their entire length. The edge was turned over inwardly and the turnover thus formed was zigzag stitched together with an elastane thread. The ends of the two copper tapes had braided cable composed of copper, 1.5 mm² in cross section, attached to them by soldering. The separation between the electrodes was 40 cm.

The current strength was measured and the resistance of the electrically conductive textiles thus obtained was determined. The results are summarized in Table 1.

TABLE 1

| | | | | P | P/F [W/ |
|---|---|---|---|---|---|
| | U [V] | I [A] | R [Ω] | [W] | m²]*⁾ |
| Example 1 | 6 | 2.3 | 2.6 | 14 | 52 |
| | 12 | 4.5 | 2.7 | 54 | 338 |
| | 18 | 6.5 | 2.8 | 117 | 731 |
| Example 2 | 6 | 1.6 | 3.75 | 10 | 45 |
| | 12 | 3.3 | 3.6 | 40 | 250 |
| | 18 | 4.8 | 3.75 | 86 | 538 |

*⁾power per unit area

In the examples which follow (i.e., examples 3-10), a sheet material produced according to Example 2 was laminated with different materials. The following materials were used for laminating:
Nonwoven: Limould 5 FR 27019, basis weight 120 g/m², manufacturer: Libeltex, 8760 Meulebeke Belgium.
Spun lace web: 70/30 viscose/polyester, 50 g/m², manufacturer: Freudenberg, Weinheim, Germany.
Charmeuse: 45 g/m², polyamide, ecru, manufacturer: Boos, Goch, Germany.
Polyester urethane foam foil: basis weight 120 g/m², manufacturer: Epurex, Walsrode, Germany.

### Example 3

A sheet material produced as per Example 2 was laminated on the coated side with nonwoven and on the reverse side with foam foil and thereon with spun lace web.

### Example 4

A sheet material produced according to Example 2 was laminated on the coated side with foam foil and thereon with Charmeuse. The reverse side was laminated with nonwoven.

### Example 5

A sheet material produced according to Example 2 was laminated with nonwoven on both sides.

### Example 6

A sheet material produced according to Example 2 was laminated on both sides with a foam foil and thereon with Charmeuse.

### Example 7

A sheet material produced according to Example 2 was laminated on the coated side with foam foil and thereon with Charmeuse. The reverse side was laminated with nonwoven.

### Example 8

A sheet material produced according to Example 2 was laminated on the coated side with nonwoven and on the reverse side with foam foil and thereon with Charmeuse.

### Example 9

A sheet material produced according to Example 2 was laminated on the coated side with foam foil and thereon with spun lace web. The reverse side was laminated with nonwoven.

### Example 10

A sheet material produced according to Example 2 was laminated on the coated side with nonwoven and on the reverse side with foam foil and thereon with spun lace web.

The current strength was measured and the resistance of the laminated textiles was determined. The results are summarized in Table 2.

TABLE 2

| | I [A] | | | | | | | |
|---|---|---|---|---|---|---|---|---|
| U [V] | Ex. 3 | Ex. 4 | Ex. 5 | Ex. 6 | Ex. 7 | Ex. 8 | Ex. 9 | Ex. 10 |
| 6 | 1.7 | 1.3 | 1.6 | 2.0 | 1.3 | 2.1 | 1.0 | 1.5 |
| 12 | 3.4 | 2.7 | 3.2 | 4.0 | 2.6 | 4.1 | 2.1 | 2.9 |
| 18 | 4.8 | 3.8 | 4.6 | 5.3 | 3.8 | 5.8 | 3.0 | 4.2 |

1. An electrically conductive, flexible sheet material assembly, comprising:
a flexible, electrically nonconductive sheetlike carrier;
a polymer-bound electrically conductive coating on said electrically nonconductive sheetlike carrier;
at least two electrodes for supplying electric current formed as flexible tape composed of an electrically conductive material, wherein each of said electrodes is fixed by way of one or more stitches on said sheetlike carrier such that at least one face of said electrode is in areal contact with said electrically conductive coating.

2. The sheet material assembly according to claim 1, wherein said electrodes and said sheetlike carrier are disposed relative to each other such that each by a top side and a bottom side of each said electrode is in contact with said electrically conductive coating.

3. The sheet material assembly according to claim 2, wherein two electrodes are disposed at opposite edges of said sheetlike carrier, said opposite edges are each turned over such that the respective said electrode is in contact with said electrically conductive coating by the top side and the bottom side of the respective said electrode being in contact with the electrically conductive coating.

4. The sheet material assembly according to claim 1, wherein said electrodes are formed of a foil material having a two-sided metallic surface or a narrow tape formed from metallic or metalized threads.

5. The sheet material assembly according to claim 1, wherein said stitches are formed by elastic threads.

6. The sheet material assembly according to claim 1, wherein said electrically conductive coating consists essentially of a polymeric binder and an electrically conductive powder in a powder-to-binder volume ratio ranging from 1:1 to 10:1.

7. The sheet material assembly according to claim 6, wherein said electrically conductive powder is a powder material having a noble metal coating disposed on a core of insulator material.

8. The sheet material assembly according to claim 1, wherein said flexible sheetlike carrier is formed of a material selected from the group consisting of textile, plastics foil, leather, and artificial leather.

9. The sheet material assembly according to claim 1, wherein a side of the assembly having said electrically conductive coating is laminated.

10. The sheet material assembly according to claim 1, wherein both sides of the assembly are laminated.

11. A flexible electric heating element, comprising the electrically conductive flexible sheet material assembly according to claim 1.

12. A heatable item of apparel, comprising the electrically conductive flexible sheet material assembly according to claim 1 incorporated into the apparel.

13. An electric heating element, comprising an electrically conductive flexible sheet material assembly according to claim 1, electric lines for feeding electric current connected to said electrodes, and means for controlling a current flow through said electrically conductive sheet material assembly.

14. The electric heating element according to claim 13 integrated in and heating areas of a passenger compartment in a vehicle.

15. An automotive seat, comprising at least one heating element incorporated in a seating area thereof, said heating element including an electrically conductive flexible sheet material assembly according to claim 1, electric lines for feeding electric current connected to said electrodes, and means for controlling a current flow through said heating element.

16. A heating blanket, comprising at least one heating element incorporated in the blanket, said heating element including an electrically conductive flexible sheet material assembly according to claim 1, electric lines for feeding electric current connected to said electrodes, and means for controlling a current flow through said heating element.

17. An item of apparel, comprising:
an electrically conductive flexible sheet material assembly according to claim 1;
at least one sensor and/or actuator for receiving information and converting the information into electrical signals;
at least one electrical connector for connecting devices for processing the electrical signals;
wherein said at least one sensor and/or actuator is connected to said at least one connector by way of said electrically conductive flexible sheet material assembly.
